(19) United States
(12) Patent Application Publication
(10) Pub. No.: US 2011/0281411 A1
(43) Pub. Date: Nov. 17, 2011

(54) METHOD FOR MANUFACTURING SEMICONDUCTOR DEVICE

(75) Inventor: Hiroyuki KITAMURA, Tokyo (JP)

(73) Assignee: ELPIDA MEMORY, INC., TOKYO (JP)

(21) Appl. No.: 13/103,595

(22) Filed: May 9, 2011

(30) Foreign Application Priority Data
May 11, 2010 (JP) 2010-109180

(51) Int. Cl. H01L 21/336; H01L 21/20

(52) U.S. Cl. 438/268; 438/478; 438/488; 257/E21.41; 257/E21.09

(57) ABSTRACT

An amorphous silicon layer and a single crystal silicon layer are formed in an upper portion of a silicon pillar. Then, by performing the selective epitaxial growth method twice, an amorphous silicon layer and an amorphous silicon germanium layer are formed in this order on the silicon pillar. Subsequently, by heat treatment, a second impurity diffusion layer including a single crystal silicon layer is formed in the upper portion of the silicon pillar. At the same time of the formation of the second impurity diffusion layer, a first contact plug including a single crystal silicon layer and a polycrystalline silicon germanium layer is formed on the silicon pillar. Then, a second contact plug made of metal is formed so that it is connected to the first contact plug.

This application is based upon and claims the benefit of priority from Japanese Patent Application No. 2010-109180, filed on May 11, 2010, the disclosure of which is incorporated herein in its entirety by reference.

### TECHNICAL FIELD

The present invention relates to a method for manufacturing semiconductor device.

### BACKGROUND ART

As disclosed in JP2008-300623 A1, as the semiconductor devices have been miniaturized, vertical type MOS transistors have been developed instead of the conventional planar type MOS transistors. In the vertical type MOS transistors, impurity diffusion layers, as source and drain electrodes, are arranged in an upper portion and a lower portion of a pillar formed on a semiconductor substrate.

When forming a contact plug that is connected to the impurity diffusion layer arranged in an upper portion of the pillar, it is preferable to provide a single crystal silicon layer, which is formed by an expitaxial growth method, between the pillar and the contact plug, as disclosed in JP2008-300623 A1. By forming such structure, even when an alignment deviation between the contact plug and the pillar is caused, it is possible to prevent the short circuit between a gate electrode and the source and drain electrodes adjacent to the upper portion of the pillar.

As disclosed in JP-A 08-293465, as another method of reducing a connection resistance of the contact plug, a method is known which crystallizes a part of amorphous silicon to form the contact plug.

In addition, as disclosed in JP-A No. 10-163124, a three-layered contact plug is known in which single crystal silicon layers are arranged above and below a single crystal silicon-germanium layer.

### SUMMARY OF THE INVENTION

In one embodiment, there is provided a method of manufacturing a semiconductor device, comprising:

etching a single crystal semiconductor substrate to form a silicon pillar;

forming a gate insulation film on a side surface of the silicon pillar;

forming a first impurity diffusion layer in a lower portion of the silicon pillar and a region contacting with the silicon pillar in the single crystal semiconductor substrate;

forming a gate electrode on the gate insulation film;

performing ion implantation of a group IV element and an impurity element into an upper portion of the silicon pillar, to form a second amorphous silicon layer containing the group IV element and the impurity element and a first single crystal silicon layer containing the impurity element in this order from an upper end of the silicon pillar;

forming a third amorphous silicon layer on the silicon pillar by a first selective epitaxial growth method;

forming an amorphous silicon germanium layer on the third amorphous silicon layer by a second selective epitaxial growth method;

performing a heat treatment to convert the second amorphous silicon layer into a second single crystal silicon layer, thereby forming a second impurity diffusion layer including the second single crystal silicon layer and the first single crystal silicon layer and to convert the third amorphous silicon layer and the amorphous silicon germanium layer into a third single crystal silicon layer and a polycrystalline silicon germanium layer in this order from the second impurity diffusion layer, thereby forming a first contact plug; and

forming a second contact plug comprising metal so as to be connected to the first contact plug.

In another embodiment, there is provided a method of manufacturing a semiconductor device, comprising:

forming a first single crystal silicon layer containing an impurity element;

forming a second amorphous silicon layer containing a group IV element on the first single crystal silicon layer;

forming a third amorphous silicon layer on the second amorphous silicon layer by a first selective epitaxial growth method;

forming an amorphous silicon germanium layer on the third amorphous silicon layer by a second selective epitaxial growth method;

performing a heat treatment to convert the second amorphous silicon layer into a second single crystal silicon layer and to convert the third amorphous silicon layer and the amorphous silicon germanium layer into a third single crystal silicon layer and a polycrystalline silicon germanium layer in this order from the second single crystal silicon layer, thereby forming a first contact plug; and

forming a second contact plug comprising metal so that the second contact plug is connected to the first contact plug.

In another embodiment, there is provided a method of manufacturing a semiconductor device, comprising:

converting an upper portion of a first single crystal silicon layer to a first amorphous silicon layer on the first single crystal silicon layer;

forming a second amorphous silicon layer on the first amorphous silicon layer;

forming an amorphous silicon germanium layer on the second amorphous silicon layer; and

performing a heat treatment to convert a first stacked layer including the first amorphous silicon layer, the second amorphous silicon layer and the amorphous silicon germanium layer to a second stacked layer including a second single crystal silicon layer, a third single crystal silicon layer and a polycrystalline silicon germanium layer.

### BRIEF DESCRIPTION OF THE DRAWINGS

The above features and advantages of the present invention will be more apparent from the following description of certain preferred embodiments taken in conjunction with the accompanying drawings, in which:

FIGS. 1 to 14 show a method of manufacturing a semiconductor device according to a first illustrative embodiment.

In the drawings, reference numerals have the following meanings: 1; semiconductor substrate, 2; device isolation area, 3, 7; silicon oxide film, 4; mask silicon nitride film, 5; silicon pillar, 6: sidewall insulation film, 8; gate insulation film, 10; first impurity diffusion layer, 11; gate electrode, 12; first interlayer insulation film, 15; first single crystal silicon layer, 15a; second impurity diffusion layer, 16; second amorphous silicon layer, 17; single crystal silicon layer, 17a; amorphous silicon layer, 18; polycrystalline silicon germanium layer, 18a; amorphous silicon germanium layer, 19; first contact plug, 20; second interlayer insulation film, 21a; second contact plug, 21b; third contact plug, 25; metal wire

### DESCRIPTION OF PREFERRED ILLUSTRATIVE EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Exemplary Embodiment

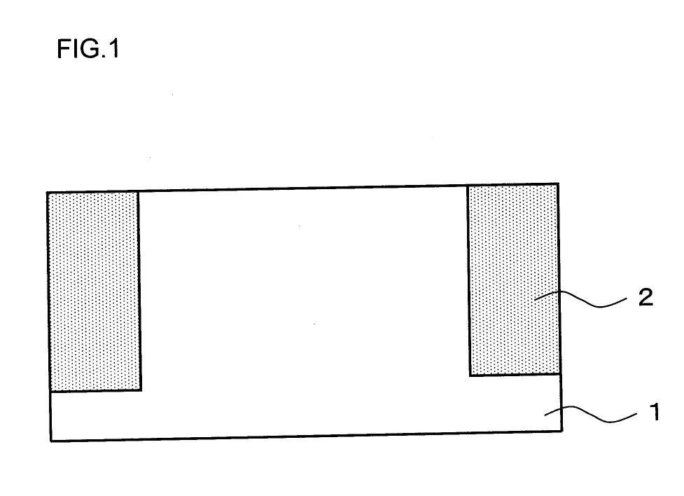

In this exemplary embodiment, a method of forming an N-type channel vertical type MOS transistor. FIGS. 1 to 14 are longitudinal sectional views showing a manufacturing method of this illustrative embodiment.

As shown in FIG. 1, isolation region 2 is formed on a semiconductor substrate 1 made of P-type single crystal silicon (Si) by embedding an insulating film with a Shallow Trench Isolation (STI) method and the like. A vertical type MOS transistor is formed in an area (active area) defined by the isolation region 2.

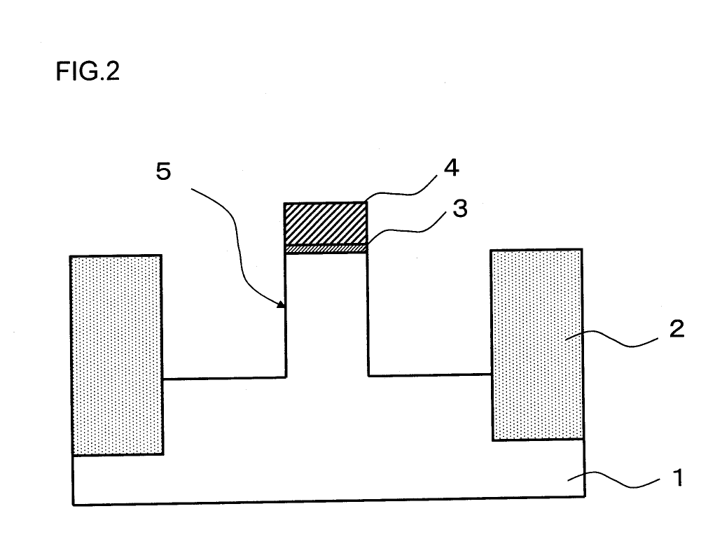

As shown in FIG. 2, a silicon oxide (SiO₂) film 3 having a thickness of about 4 to 5 nm is formed on a surface of the semiconductor substrate 1 by a thermal oxidation method and silicon nitride (Si₃N₄) film 4 having a thickness of about 120 nm is then deposited thereon by a CVD method. Subsequently, a patterning is performed by using a photolithography technology, to form a mask silicon nitride film 4.

Then, anisotropic dry etching is performed using the mask silicon nitride film 4 as a mask, to form a silicon pillar 5 on the semiconductor substrate 1. At this time, the isolation region 2 remains without being etched. A planar shape of the silicon pillar 5 is not particularly limited. For example, when the planar shape is rectangular, it may be possible to make a square having a side of about 60 nm. In addition, a height of the silicon pillar 5 (etching depth of the semiconductor substrate 1) may be about 200 nm.

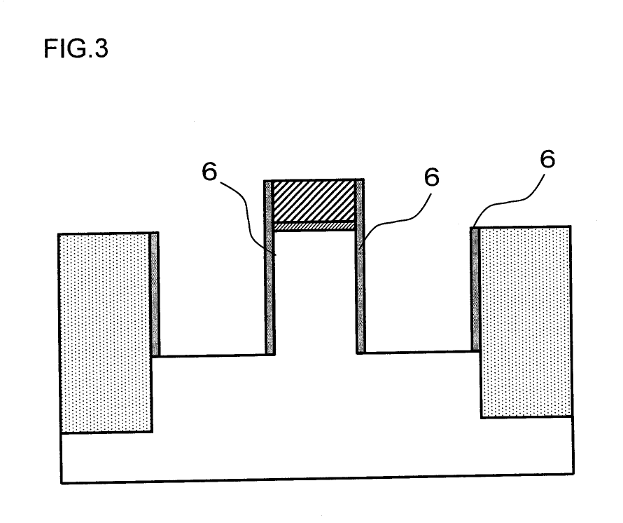

As shown in FIG. 3, after a silicon nitride film 6 is deposited by the CVD method, the etch back is performed to form sidewall insulation films 6 that cover side surfaces of the silicon pillar 5. At this time, in the active area except for the silicon pillar 5, the silicon surface of the semiconductor substrate 1 is exposed.

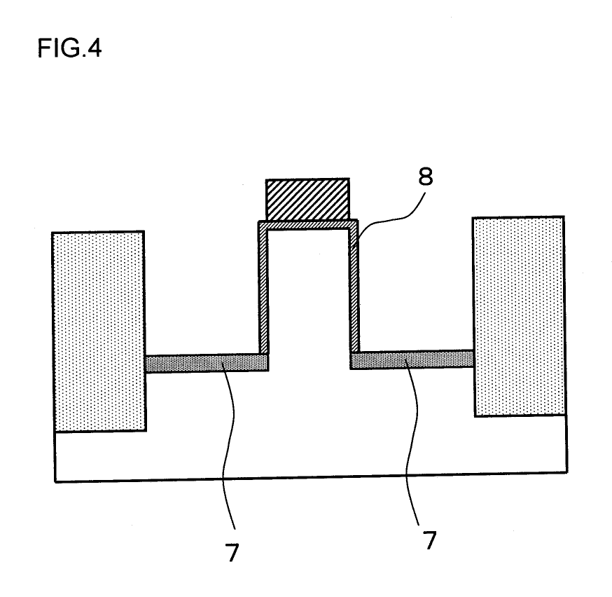

As shown in FIG. 4, a silicon oxide film 7 having a thickness of about 30 nm is formed in the area, in which the silicon surface is exposed, by the thermal oxidation method and the sidewall insulation films 6 are then removed by wet etching. At this time, since the mask silicon nitride film 4 is also wet etched, the wet etching time is set in such a way that the mask silicon nitride film 4 remains on the silicon pillar 5.

Subsequently, a gate insulation film 8 is formed on the side surfaces of the silicon pillar 5. A silicon oxide film having a thickness of about 4 nm formed by the thermal oxidation method may be exemplified as the gate insulation film 8. The gate insulation film may be also formed using a high-K film (high dielectric film).

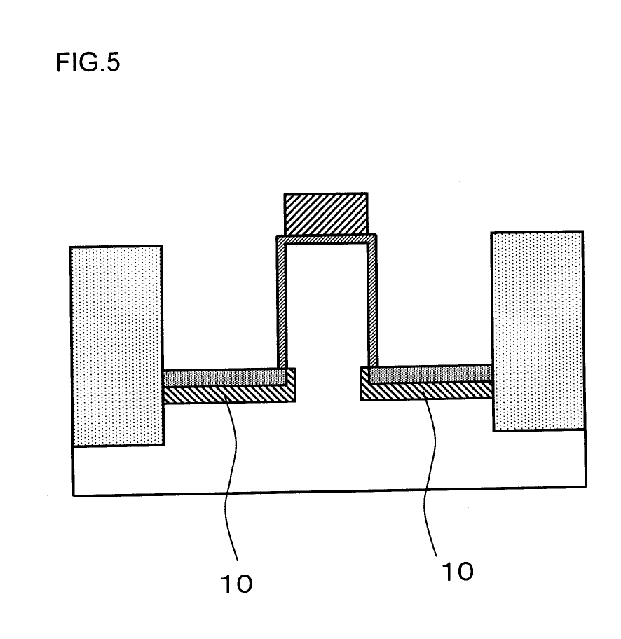

As shown in FIG. 5, N-type impurities having a dose of about 3×10¹⁵ atoms/cm² such as arsenic are introduced into the semiconductor substrate 1 by an ion implantation method. By performing an annealing treatment under nitrogen atmosphere of high temperature, a first impurity diffusion layer 10 is diffused to a lower portion of the silicon pillar and the semiconductor substrate 1 below of the pillar 5, so that one of source and drain electrodes of the vertical type MOS transistor is formed. In the meantime, considering a thermal hysteresis during a following process, the annealing process may be omitted at this time.

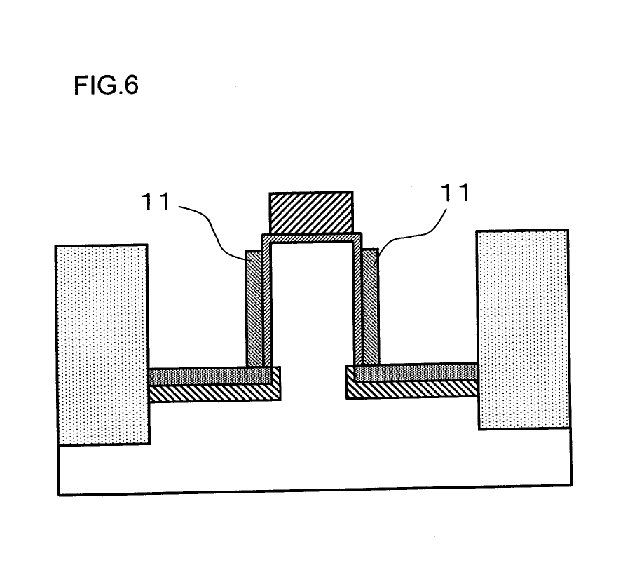

As shown in FIG. 6, by performing the etch back after depositing a conductive film, a gate electrode 11 is formed on the side surfaces of the silicon pillar 5. As the material of the gate electrode, a polycrystalline silicon film containing impurities such as phosphorus, a metal film such as tungsten (W), a metal silicide film such as WSi, a metal nitride film such as WN, and a stacked film thereof may be exemplified. The gate electrode also remains on the side surfaces of the isolation region 2. However, since it does not contribute to an operation of the transistor, it is omitted in FIG. 6.

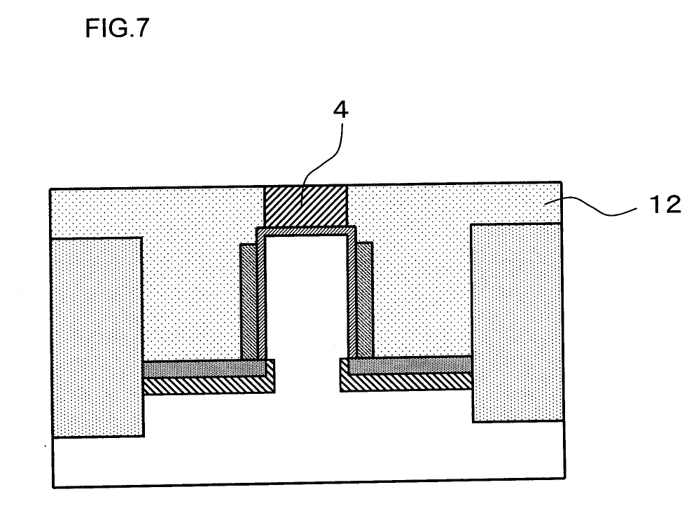

As shown in FIG. 7, silicon oxide is deposited in order to embed the silicon pillar 5 by the CVD method, thereby forming a first interlayer insulation film 12. Then, a surface thereof is planarized by performing Chemical Mechanical Polishing (CMP). The CMP process is stopped when an upper surface of the mask silicon nitride film 4 is exposed.

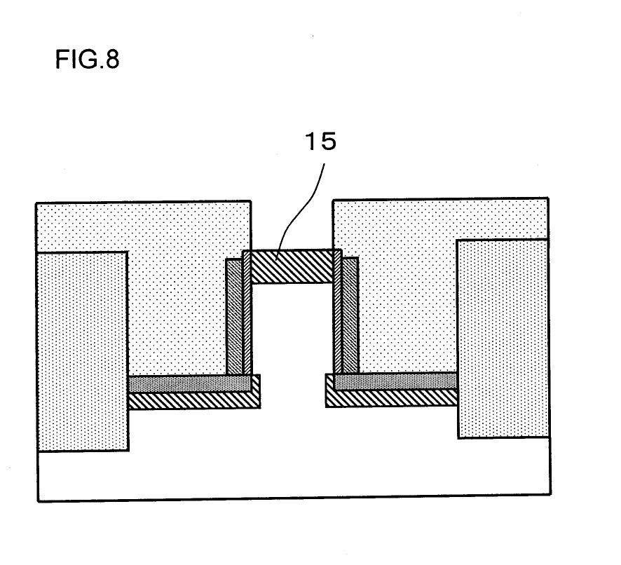

As shown in FIG. 8, the mask silicon nitride film 4 is removed by the wet etching, to form an open hole. Then, N-type impurities having a dose of about 3×10¹⁵ atoms/cm² such as arsenic (As) are introduced into the upper portion of the silicon pillar 5 by the ion implantation method (corresponds to the ion implantation of impurity element), to form a first single crystal silicon layer 15 containing the N-type impurity element is formed.

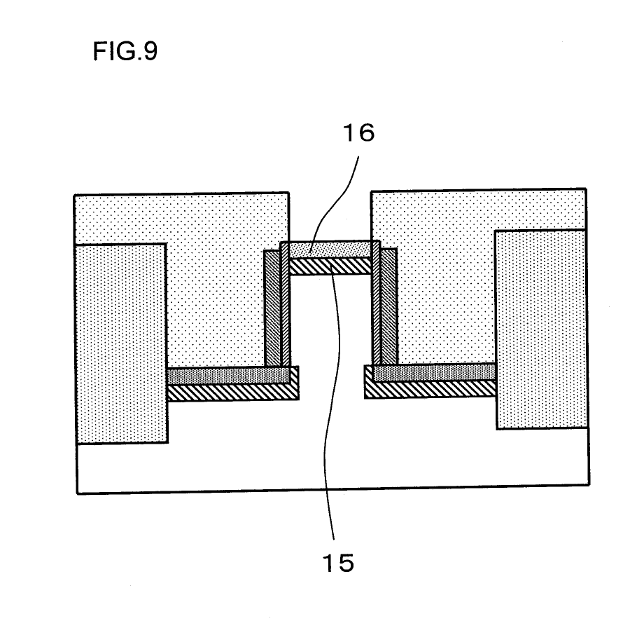

As shown in FIG. 9, carbon, which belongs to the group IV, is ion-implanted (corresponds to the ion implantation of the group IV element) under conditions of 5 to 10 KeV energy and a dose of 5×10¹⁵ to 1×10¹⁶ atoms/cm². Thereby, an upper portion of the first single crystal silicon layer 15 is armophized, to form a second amorphous silicon layer 16 containing the N-type impurity element and the group IV element. As the group IV element that is ion-implanted, silicon or germanium may be used in addition to carbon.

The sequences of forming the first single crystal silicon layer 15 and ion-implanting the group IV element may be performed in reverse order. Even in this case, the N-type impurity element is introduced into the second amorphous silicon layer 16 containing the group IV element and an area below the layer and the first single crystal silicon layer 15 containing the N-type impurity element is formed below the second amorphous silicon layer 16.

The first single crystal silicon layer 15 into which the impurity element is introduced serves as the other of the source and drain electrodes through a process that is described below. In this exemplary embodiment, the group IV element is introduced into only the upper portions of the source and drain electrodes, so that it is possible to form the second amorphous silicon layer 16 while suppressing the influence on the operating characteristics of the MOS transistor.

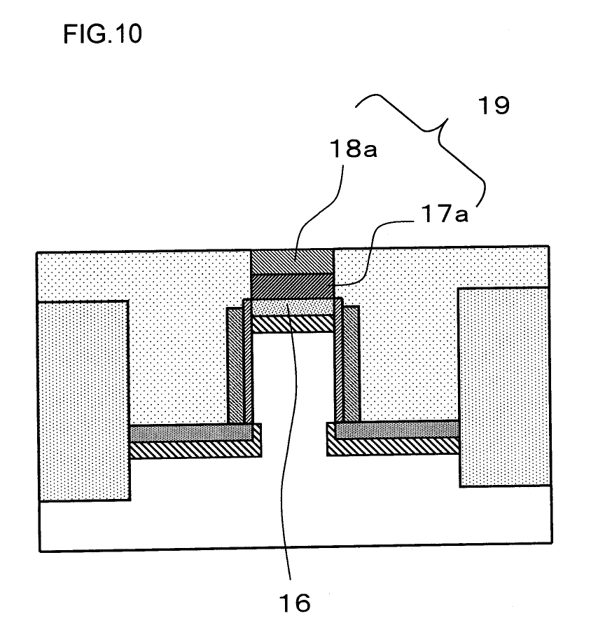

As shown in FIG. 10, by performing a chemical liquid process using dilute hydrofluoric acid and a high temperature heating process under vacuum, the silicon oxide film 3 and the natural oxide film on the upper surface of the silicon pillar 5, are removed to expose the clean silicon surface.

By the selective epitaxial growth method, two amorphous layers are formed. At this time, in a first step, SiH₄ gas is used to form a third amorphous silicon layer 17a having an about half height of the open hole. Then, in a second step, SiH₄ gas and GeH₄ gas are used to form an amorphous silicon germanium (Si—Ge) layer 18a until its height is substantially flush with the upper surface of the first interlayer film 12. It may be possible that a position of the upper surface of the amorphous silicon germanium layer 18a is not necessarily equal to the upper surface of the first interlayer film 12.

Since first, the second amorphous silicon layer 16 is beforehand formed adjacent to the upper surface of the silicon pillar 5, the third amorphous silicon layer 17a and the amorphous silicon germanium layer 18a are formed by the selective epitaxial growth method.

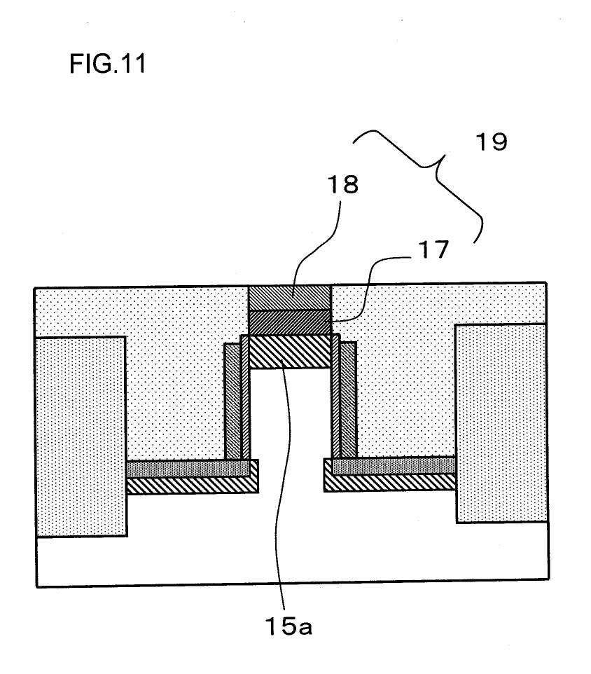

As shown in FIG. 11, the annealing process is performed under nitrogen atmosphere of high temperatures (900 to 1,000° C.) by lamp heating. Since the second amorphous silicon layer 16 is contacted to the single crystal silicon layer 15 of the lower layer, the second amorphous silicon layer 16 is single-crystallized from a lower portion thereof and becomes thus a second single crystal silicon layer. Thereby, a boundary between the first and second single crystal silicon layers disappears, so that a second impurity diffusion layer 15a being the single crystal silicon layer is formed as the other of the source and drain electrodes of the vertical type MOS transistor.

By the annealing, the third amorphous silicon layer 17a continuing to the second amorphous silicon layer 16 is also single-crystallized and becomes thus a third single crystal silicon layer 17. In the meantime, since the amorphous silicon germanium layer 18a positioned at the top part does not contact the single crystal silicon layer, it is poly-crystallized from an upper portion thereof and becomes thus a polycrystalline silicon germanium layer 18. Then, a first contact plug 19 including the third single crystal silicon layer 17 and the polycrystalline silicon germanium layer 18 is formed. In the meantime, it is not necessary that a boundary between the third amorphous silicon layer 17a and the amorphous silicon germanium layer 18a be maintained as a boundary between the single crystal layer and the poly crystal layer before the annealing treatment is performed. For example, a part of the upper portion of the third amorphous silicon layer 17a may be silicon-poly crystallized.

In this exemplary embodiment, the connection part between the silicon pillar 5 and the first contact plug 19 may be made of the single crystal silicon layer 17 and the upper end portion of the first contact plug may be made of the polycrystalline silicon germanium layer 18.

After performing the annealing treatment, the N-type impurities (phosphorous or arsenic) are introduced into the first contact plug 19 with a dose of about 1×10¹⁵ to 5×10¹⁵ atoms/cm² by the ion implantation. Then, the annealing such as lamp heating may be further performed to activate the impurities introduced into the first contact plug 19. Also, instead of introducing the N-type impurities into the first contact plug 19 by the ion implantation, gas containing N-type impurities, such as PH₃ (phosphine) gas, may be added when forming the first contact plug 19 by the selective epitaxial growth method, thereby forming a film with the N-type impurities being contained.

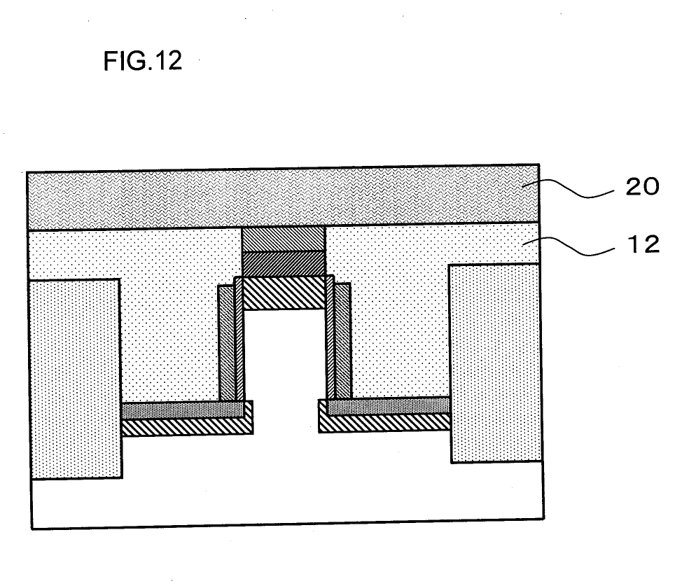

As shown in FIG. 12, silicon oxide is deposited on the first interlayer insulation film 12 by the CVD method to form a second interlayer insulation film 20. Then, the CMP is performed to planarize a surface thereof.

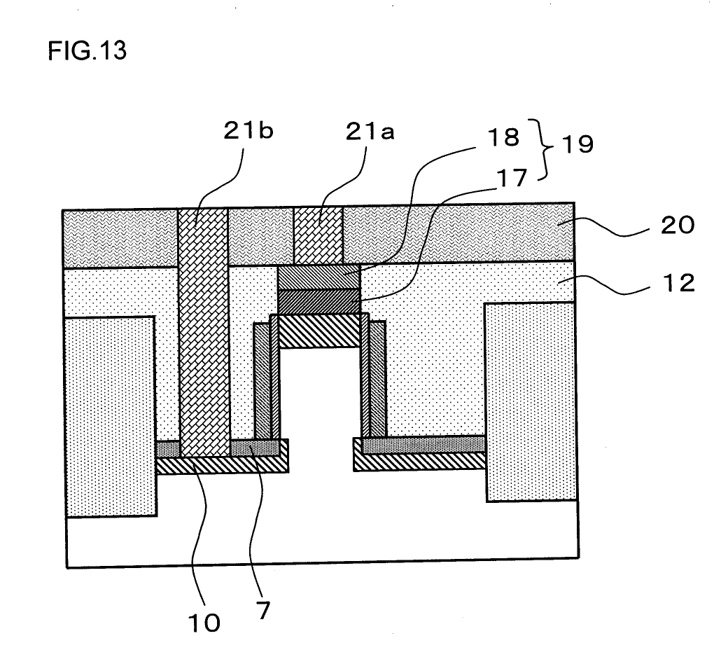

As shown in FIG. 13, a second contact plug 21a, which penetrates the second interlayer insulation film 12 and connects to the first contact plug, is formed using a metal film. As the metal film, a stacked film, which is obtained by sequentially forming titanium (Ti) and titanium nitride (TiN) as a barrier film and then depositing tungsten (W), may be exemplified.

In this exemplary embodiment, the metal film (titanium film) of a bottom surface of the second contact plug 21a contacts with the polycrystalline silicon germanium layer 18 of the upper surface of the first contact plug are contacted, thereby reducing the connection resistance. This is because a bandgap width (1.11 eV) of the silicon layer is reduced due to the containing of germanium and the connection resistance between the metal and silicon germanium layers is thus reduced.

In addition, in this exemplary embodiment, the connection portion between the silicon pillar 5 and the first contact plug is Si single-crystallized, resulting in reducing also the connection resistance in the connection portion. Additionally, sicne the second contact plug 21a is made of the metal film, the electric resistance of the second contact plug itself can be also reduced.

A third contact plug 21b is formed of the same metal material as the second contact plug 21a. The third contact plug 21b penetrates the second interlayer insulation film 20, the first interlayer insulation film 12 and the silicon oxide film 7 to connect to the first impurity diffusion layer 10. The second contact plug 21a and the third contact plug 21b may be formed at the same time. Since the third contact plug 21b can be formed at a position distant from the gate electrode 11, it is not necessary to provide the third contact plug with the intermediate structure, like the first contact plug 19, so that the metal film can be directly connected to the first impurity diffusion layer 10. Accordingly, it is possible to obtain the lower connection resistance.

The first contact plug 19 is formed by the self alignment so that it fills the opening obtained by removing the mask silicon nitride film 4. Accordingly, it is possible to avoid the short circuit to the gate electrode without causing the alignment deviation. In addition, although not shown, the contact plug that is connected to the gate electrode 11 is formed using the technology (for example, JP2008-300623 A1) of making the drawing pillar be adjacent.

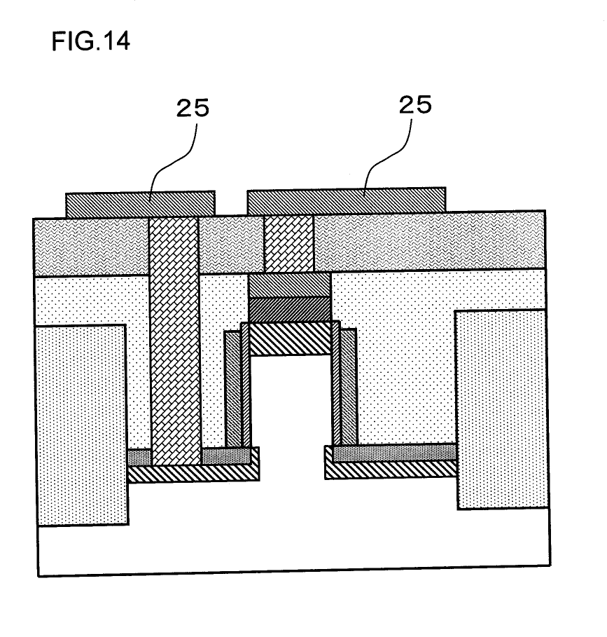

As shown in FIG. 14, a metal wire 25 that is connected to the second and third contact plugs 21a, 21b is formed using aluminum (Al), copper (Cu) and the like, resulting in completing a vertical type MOS transistor. According to this vertical type MOS transistor, the connection resistance between the second impurity diffusion layer and the first contact plug and the connection resistance between the first and second contact plugs are reduced, thereby increasing the on current. As a result, it is possible to provide a semiconductor device of high performance.

In the above exemplary embodiment, the N-type channel MOS transistor has been described. However, instead of introducing the N-type impurity element, it is possible to introduce the P-type impurities such as boron (B), thereby forming a P-type channel vertical type MOS transistor. When using the P-type semiconductor substrate 1, an N-type well is beforehand provided in an area in which a P-type channel MOS transistor is to be formed. In addition, it may be possible to separately form an N-type channel vertical type MOS transistor and a P-type channel vertical type MOS transistor on a same semiconductor substrate, thereby forming a circuit configuring a CMOS.

When amorphizing the single crystal silicon layer adjacent to the upper surface of the silicon pillar in the P-type channel MOS transistor, the group IV element is ion-implanted into the upper portion of the silicon pillar, likewise the N-type channel MOS transistor. Also in this case, the sequences of ion-implanting the P-type impurity element and the group IV element are not important, and any of ion-implantations of the P-type impurity element and the group IV element may be performed in first. When the P-type impurity element is ion-implanted, the energy of ion implantation is controlled so that the P-type impurities are ion-implanted into both the area below the group IV impurity elements-introduced second amorphous silicon layer and the second amorphous silicon layer. In addition, likewise the N-type channel MOS transistor, it is possible to form the first, second and third contact plugs in the P-type channel MOS transistor. The P-type impurities may be introduced into the first contact plug and the second and third contact plugs may be formed using metal films, as described above.

It is apparent that the present invention is not limited to the above embodiments, but may be modified and changed without departing from the scope and spirit of the invention.

In addition, while not specifically claimed in the claim section, the applications reserve the right to include in the claim section at any appropriate time the following method:

1. A semiconductor device, comprising:

a silicon pillar formed upward from a main surface of a silicon substrate;

a gate electrode covering sides surface of the silicon pillar via a gate insulation film;

a first impurity diffusion layer formed in a lower portion of the silicon pillar;

a second impurity diffusion layer formed in an upper portion of the silicon pillar and made of single crystal silicon;

a first contact plug including a third single crystal silicon layer and a polycrystalline silicon germanium layer formed in this order on the second impurity diffusion layer; and a second contact plug formed on the first contact plug and made of metal.

2. The semiconductor device according to the above 1, further comprising:

a third contact plug connected to the first impurity diffusion layer; and

a metal wire connected to the second and third contact plugs.

What is claimed is:

1. A method of manufacturing a semiconductor device, comprising:
etching a single crystal semiconductor substrate to form a silicon pillar;
forming a gate insulation film on a side surface of the silicon pillar;
forming a first impurity diffusion layer in a lower portion of the silicon pillar and a region contacting with the silicon pillar in the single crystal semiconductor substrate;
forming a gate electrode on the gate insulation film;
performing ion implantation of a group IV element and an impurity element into an upper portion of the silicon pillar, to form a second amorphous silicon layer containing the group IV element and the impurity element and a first single crystal silicon layer containing the impurity element in this order from an upper end of the silicon pillar;
forming a third amorphous silicon layer on the silicon pillar by a first selective epitaxial growth method;
forming an amorphous silicon germanium layer on the third amorphous silicon layer by a second selective epitaxial growth method;
performing a heat treatment to convert the second amorphous silicon layer into a second single crystal silicon layer, thereby forming a second impurity diffusion layer including the second single crystal silicon layer and the first single crystal silicon layer and to convert the third amorphous silicon layer and the amorphous silicon germanium layer into a third single crystal silicon layer and a polycrystalline silicon germanium layer in this order from the second impurity diffusion layer, thereby forming a first contact plug; and
forming a second contact plug comprising metal so as to be connected to the first contact plug.

2. The method according to claim 1,
wherein the forming of the second amorphous silicon layer and the first single crystal silicon layer comprises:
ion-implanting an N-type or P-type impurity element into the upper portion of the silicon pillar, to form the first single crystal silicon layer containing the impurity element in the upper portion of the silicon pillar; and
after the ion implantation of the impurity element, ion-implanting the group IV element into an upper portion of the first single crystal silicon layer, to make the upper portion of the first single crystal silicon layer into the second amorphous silicon layer.

3. The method according to claim 1,
wherein the forming of the second amorphous silicon layer and the first single crystal silicon layer comprises:
ion-implanting the group IV element into the upper portion of the silicon pillar, to make the upper portion of the silicon pillar into the second amorphous silicon layer; and
after the ion implantation of the group IV element, ion-implanting an N-type or P-type impurity element into a region of the silicon pillar including the second amorphous silicon layer and a part positioned below the second amorphous silicon layer, to form the first single crystal silicon layer below the second amorphous silicon layer.

4. The method according to claim 2,
wherein the group IV element is at least one element selected from a group consisting of carbon, silicon and germanium.

5. The method according to claim 2,
wherein the group IV element is ion-implanted under condition of a dose of 5×10¹⁵ to 1×10¹⁶ atoms/cm².

6. The method according to claim 1,
wherein in forming the third amorphous silicon layer, the third amorphous silicon layer is formed by the first selective epitaxial growth method using SiH₄ gas.

7. The method according to claim 1,
wherein in forming the amorphous silicon germanium layer, the amorphous silicon germanium layer is formed by the second selective epitaxial growth method using SiH₄ gas and GeH₄ gas.

8. The method according to claim 6,
wherein in the first selective epitaxial growth method, a gas containing impurities having the same conductive type as the impurity element is further used.

9. The method according to claim 1,
wherein the forming the first contact plug comprises:
implanting impurities having the same conductive type as the impurity element into the third single crystal silicon layer and the polycrystalline silicon germanium layer.

10. The method according to claim 1,
wherein in forming the first contact plug, the heat treatment is performed at temperatures of 900 to 1,000° C.

11. The method according to claim 1, further comprising:
forming a third contact plug so that the third contact plug is connected to the first impurity diffusion layer.

12. The method according to claim 11, further comprising:
forming a metal wire so that the metal wire is connected to the second and third contact plugs, after forming the second and third contact plugs.

13. A method of manufacturing a semiconductor device, comprising:
forming a first single crystal silicon layer containing an impurity element;
forming a second amorphous silicon layer containing a group IV element on the first single crystal silicon layer;
forming a third amorphous silicon layer on the second amorphous silicon layer by a first selective epitaxial growth method;
forming an amorphous silicon germanium layer on the third amorphous silicon layer by a second selective epitaxial growth method;
performing a heat treatment to convert the second amorphous silicon layer into a second single crystal silicon layer and to convert the third amorphous silicon layer and the amorphous silicon germanium layer into a third single crystal silicon layer and a polycrystalline silicon germanium layer in this order from the second single crystal silicon layer, thereby forming a first contact plug; and
forming a second contact plug comprising metal so that the second contact plug is connected to the first contact plug.

14. The method according to claim 13,
wherein the group IV element is at least one element selected from a group consisting of carbon, silicon and germanium.

15. The method according to claim 13,
wherein in forming the third amorphous silicon layer, the third amorphous silicon layer is formed by the first selective epitaxial growth method using SiH₄ gas.

16. The method according to claim 13,
wherein in forming the amorphous silicon germanium layer, the amorphous silicon germanium layer is formed by the second selective epitaxial growth method using SiH₄ gas and GeH₄ gas.

17. The method according to claim 15,
wherein in the first selective epitaxial growth method, a gas containing impurities having the same conductive type as the impurity element is further used.

18. The method according to claim 13,
wherein the forming the first contact plug comprises:
implanting impurities having the same conductive type as the impurity element into the third single crystal silicon layer and the polycrystalline silicon germanium layer.

19. The method according to claim 13,
wherein in forming the first contact plug, the heat treatment is performed at temperatures of 900 to 1,000° C.

20. A method of manufacturing a semiconductor device, comprising:
converting an upper portion of a first single crystal silicon layer to a first amorphous silicon layer on the first single crystal silicon layer;
forming a second amorphous silicon layer on the first amorphous silicon layer;
forming an amorphous silicon germanium layer on the second amorphous silicon layer; and
performing a heat treatment to convert a first stacked layer including the first amorphous silicon layer, the second amorphous silicon layer and the amorphous silicon germanium layer to a second stacked layer including a second single crystal silicon layer, a third single crystal silicon layer and a polycrystalline silicon germanium layer.
